(19) United States
(12) Patent Application Publication
(10) Pub. No.: US 2016/0079261 A1
(43) Pub. Date: Mar. 17, 2016

(54) SEMICONDUCTOR MEMORY DEVICE AND METHOD FOR MANUFACTURING SAME

(71) Applicant: Kabushiki Kaisha Toshiba, Minato-ku (JP)

(72) Inventor: Yuki YAMADA, Yokkaichi (JP)

(73) Assignee: Kabushiki Kaisha Toshiba, Minato-ku (JP)

(21) Appl. No.: 14/614,745

(22) Filed: Feb. 5, 2015

Related U.S. Application Data
(60) Provisional application No. 62/048,841, filed on Sep. 11, 2014.

(51) Int. Cl. H01L 27/115; H01L 29/423; H01L 21/285; H01L 29/45; H01L 21/02; H01L 29/792; H01L 29/16

(52) U.S. Cl. CPC H01L 27/11582; H01L 29/7926; H01L 29/42344; H01L 29/16; H01L 29/456; H01L 21/02532; H01L 21/28518

(57) ABSTRACT

According to one embodiment, a semiconductor memory device includes a stacked body including a plurality of electrode layers and a plurality of insulating layers respectively provided between the plurality of electrode layers; a columnar part penetrating through the stacked body and extending in stacking direction of the stacked body; a conductive film provided on the columnar part and containing a metal; and a contact part provided on the conductive film and being in contact with the conductive film. The columnar part includes a channel body extending in the stacking direction; a charge accumulation film provided between the channel body and each of the electrode layers; and a semiconductor film provided below the conductive film, being in contact with the channel body and the conductive film, and having a higher impurity concentration than the channel body.

This application is based upon and claims the benefit of priority from U.S. Provisional Patent Application 62/048,841 field on Sep. 11, 2014; the entire contents of which are incorporated herein by reference.

### FIELD

Embodiments described herein relate generally to a semiconductor memory device and a method for manufacturing same.

### BACKGROUND

In a proposed memory device of the three-dimensional structure, a stacked body is formed by stacking a plurality of electrode layers via an insulating layer. The electrode layer functions as a control gate in a memory cell. A memory hole is formed in the stacked body. A silicon body serving as a channel is provided on the sidewall of the memory hole via a charge accumulation film.

In forming a contact part connected to the channel, it is desired to ensure electrical connection between the contact part and the memory hole part with high accuracy.

### BRIEF DESCRIPTION OF THE DRAWINGS

FIG. 1 is a schematic perspective view of a memory cell array in an embodiment;

FIG. 2 is an enlarged schematic sectional view of a part of the columnar section of the embodiment;

FIG. 3 is an enlarged schematic sectional view of a part of the columnar section of the embodiment;

FIG. 4A to FIG. 9 are schematic sectional views showing a method for manufacturing the semiconductor memory device of the embodiment;

FIG. 10 is an enlarged schematic sectional view of a part of the columnar section of another embodiment;

FIG. 11A to FIG. 12B are schematic sectional views showing a method for manufacturing the semiconductor memory device of the another embodiment; and

FIG. 13 is a schematic perspective view of another memory cell array of the semiconductor memory device of the embodiment.

### DETAILED DESCRIPTION

According to one embodiment, a semiconductor memory device includes a stacked body including a plurality of electrode layers and a plurality of insulating layers respectively provided between the plurality of electrode layers; a columnar part penetrating through the stacked body and extending in stacking direction of the stacked body; a conductive film provided on the columnar part and containing a metal; and a contact part provided on the conductive film and being in contact with the conductive film. The columnar part includes a channel body extending in the stacking direction; a charge accumulation film provided between the channel body and each of the electrode layers; and a semiconductor film provided below the conductive film, being in contact with the channel body and the conductive film, and having a higher impurity concentration than the channel body.

Embodiments will now be described with reference to the drawings. In the drawings, same components are labeled with same reference numerals.

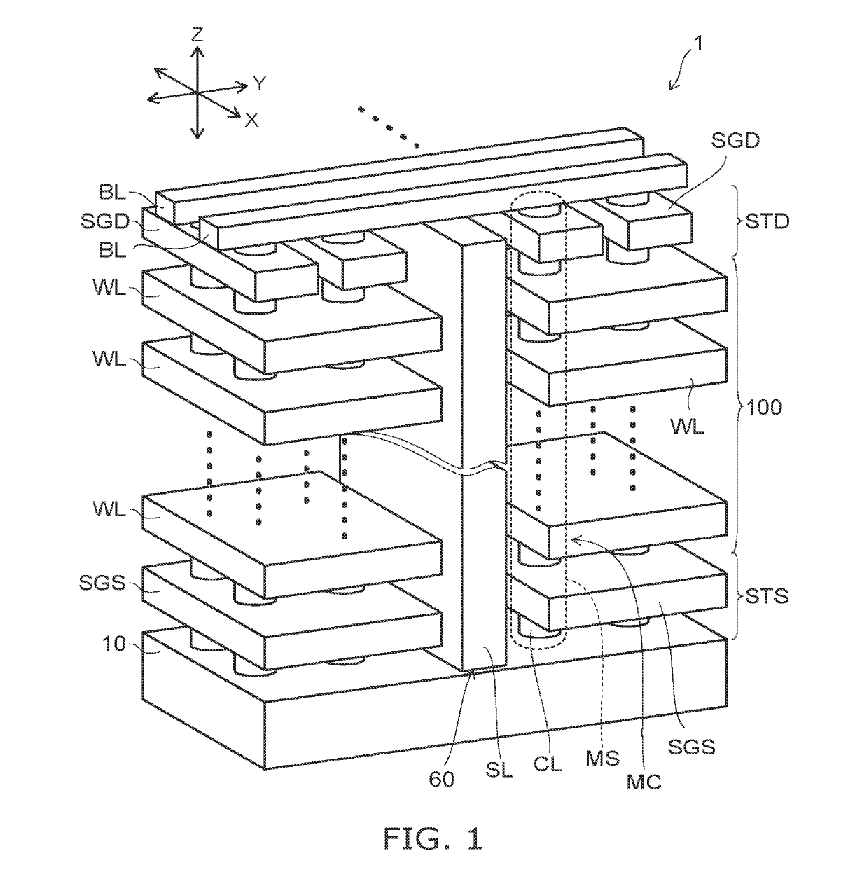

FIG. 1 is a schematic perspective view of a memory cell array 1 of an embodiment. In FIG. 1, insulating layers between the electrode layers, for instance, are not shown for clarity of illustration.

In FIG. 1, two directions orthogonal to each other are referred to as X-direction and Y-direction. The direction orthogonal to the X-direction and the Y-direction (XY-plane) is referred to as Z-direction (stacking direction). A plurality of electrode layers WL is stacked in the Z-direction.

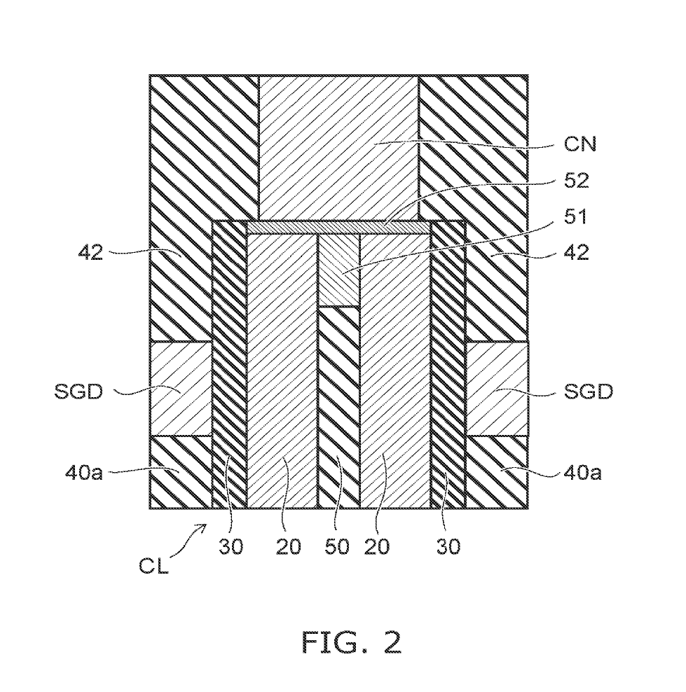

FIG. 2 is an enlarged schematic sectional view of part of a columnar part of the embodiment.

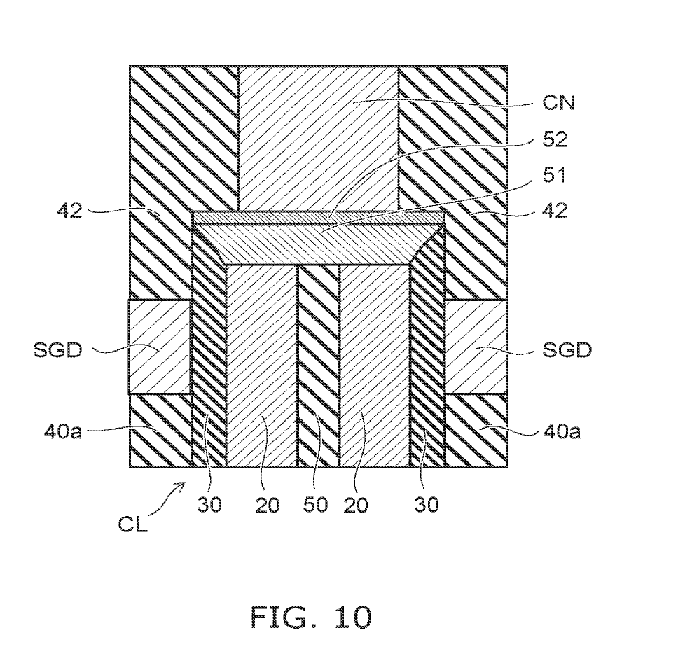

As shown in FIG. 1, the memory cell array 1 includes a plurality of memory strings MS. The main structure of the memory cell array 1 is similar also in the alternative embodiment described with reference to FIGS. 10 to 12B.

A source side select gate SGS is provided via an insulating layer 41 on a substrate 10. An insulating layer 40 is provided on the source side select gate SGS. A stacked body 100 is provided on the insulating layer 40. A plurality of electrode layers WL and a plurality of insulating layers 40 are stacked alternately one by one in the stacked body 100. The number of electrode layers WL shown in the figure is illustrative only. The number of electrode layers WL is arbitrary.

For example, the plurality of electrode layers WL is separately stacked each other. The plurality of interlayer insulating layers 40 includes an air gap.

An insulating layer 40a is provided on the uppermost electrode layer WL. A drain side select gate SGD is provided on the insulating layer 40a. An insulating layer 42 is provided on the drain side select gate SGD.

The source side select gate SGS, the drain side select gate SGD, and the electrode layer WL are silicon layers primarily containing silicon. The silicon layer is doped with e.g. boron as an impurity for providing conductivity. Alternatively, the source side select gate SGS, the drain side select gate SGD, and the electrode layer WL may contain at least one of metal and metal silicide (including metal and silicon). Alternatively, the source side select gate SGS, the drain side select gate SGD, and the electrode layer WL may be made of metal. The insulating layers 40, 40a, 41, 42 are made of insulating film primarily containing e.g. silicon oxide.

The thickness of the drain side select gate SGD and the source side select gate SGS can be thicker than the thickness of one electrode layer WL. The drain side select gate SGD and the source side select gate SGS may be provided in a plurality. The thickness of the drain side select gate SGD and the source side select gate SGS may be equal to or thinner than the thickness of one electrode layer WL. In this case, as described above, the drain side select gate SGD and the source side select gate SGS may be provided in a plurality. Here, the term “thickness” used herein refers to the thickness in the stacking direction (Z-direction) of the stacked body 100.

The stacked body 100 includes a columnar part CL extending in the Z-direction. The columnar part CL penetrates through the stacked body 100. The columnar part CL is formed like e.g. a circular or elliptic cylinder. The columnar part CL is electrically connected to the substrate 10.

The stacked body 100 includes a separation part 60 penetrating through the stacked body 100 and extending in the X-direction. An insulating film is provided on the sidewall of the separation part 60. A source layer SL, for instance, is provided inside the insulating film. The side surface of the source layer SL is covered with the insulating film. The source layer SL is made of a conductive material.

The lower end of the source layer SL is electrically connected to a channel body 20 (semiconductor body) in the columnar part CL through the substrate 10. The upper end of the source layer SL is electrically connected to a peripheral circuit through a wiring, not shown. The drain side select gate SGD and the source side select gate SGS are, for example, provided surrounding the columnar part CL including the channel body 20.

For instance, the source layer SL may be provided between the substrate 10 and the stacked body 100. In this case, a contact layer, not shown, is provided in the separation part 60. The source layer SL is electrically connected to a peripheral circuit through the contact layer.

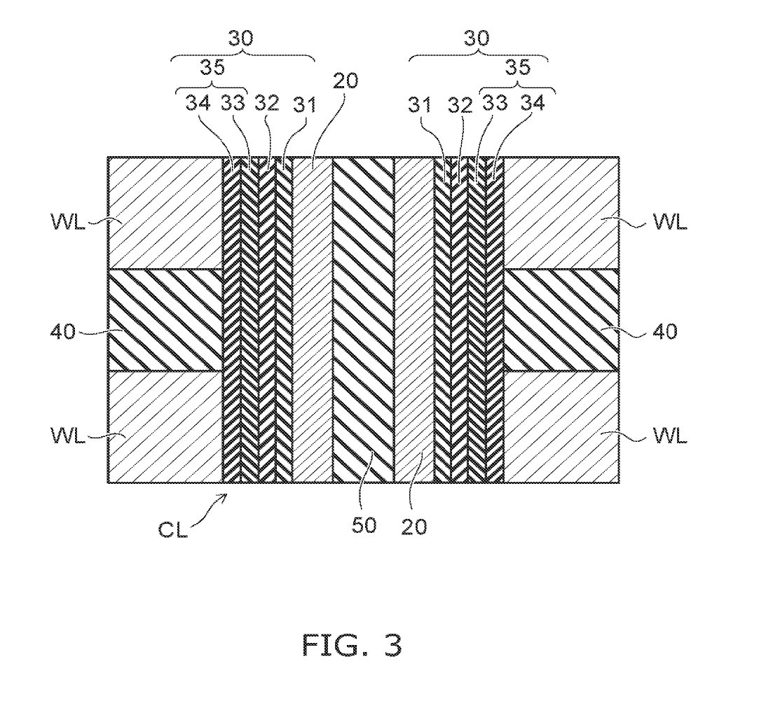

FIG. 3 is an enlarged schematic sectional view of part of the columnar part CL of the embodiment.

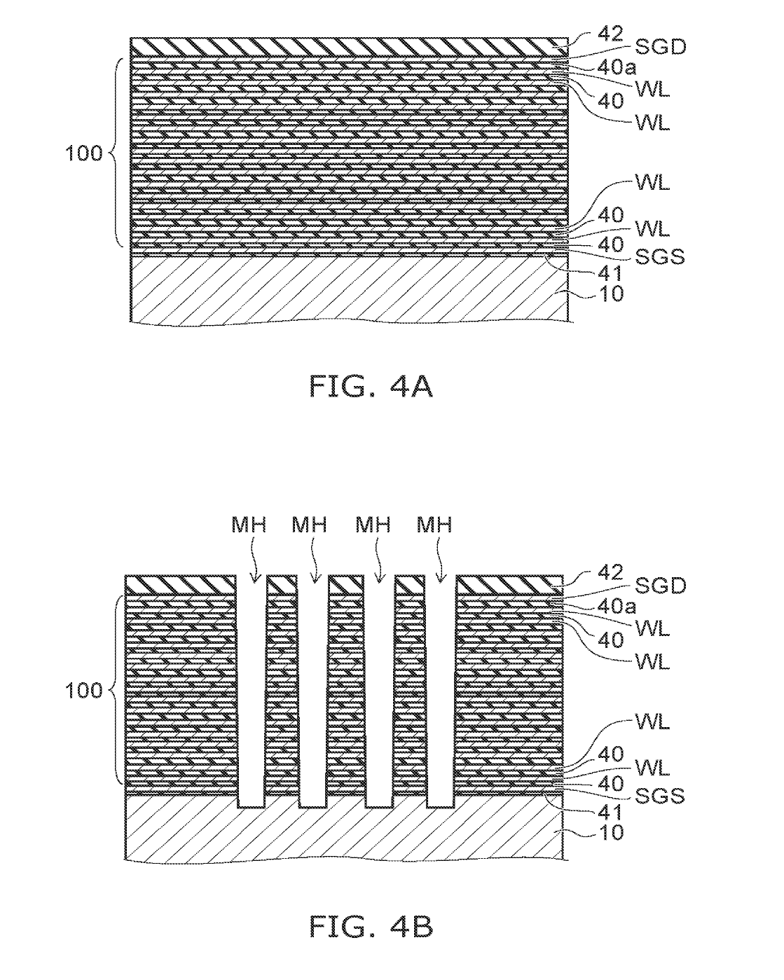

The columnar part CL is formed in a memory hole MH (FIG. 4B). The memory hole MH is formed in the stacked body 100 including a plurality of electrode layers WL and a plurality of insulating layers 40. A channel body 20 as a semiconductor channel is provided in the memory hole MH. The channel body 20 is e.g. a silicon film primarily containing silicon.

The channel body 20 is provided like a tube extending in the stacking direction of the stacked body 100. The upper end of the channel body 20 is connected to a bit line BL (wiring) shown in FIG. 1. The lower end side of the channel body 20 is connected to the substrate 10. Each bit line BL extends in the Y-direction.

A memory film 30 is provided between the electrode layer WL and the channel body 20. The memory film 30 includes a block insulating film 35, a charge accumulation film 32, and a tunnel insulating film 31.

The block insulating film 35, the charge accumulation film 32, and the tunnel insulating film 31 are provided sequentially from the electrode layer WL side between the electrode layer WL and the channel body 20. The block insulating film 35 is in contact with the electrode layer WL. The tunnel insulating film 31 is in contact with the channel body 20. The charge accumulation film 32 is provided between the block insulating film 35 and the tunnel insulating film 31.

The electrode layer WL surrounds the channel body 20 via the memory film 30. A core insulating film 50 is provided inside the channel body 20.

The channel body 20 functions as a channel in the memory cell MC. The electrode layer WL functions as a control gate of the memory cell MC. The charge accumulation film 32 functions as a data memory layer for accumulating charge injected from the channel body 20. That is, a memory cell MC is formed at the intersection of the channel body 20 and each electrode layer WL. The memory cell MC has a structure in which the channel is surrounded with the control gate.

The semiconductor memory device of the embodiment can electrically and freely erase/write data and retain its memory content even when powered off.

The memory cell MC is of e.g. the charge trap type. The charge accumulation film 32 includes a large number of trap sites for trapping charge, and is e.g. a silicon nitride film.

The tunnel insulating film 31 serves as a potential barrier when charge is injected from the channel body 20 into the charge accumulation film 32, or when the charge accumulated in the charge accumulation film 32 is diffused into the channel body 20. The tunnel insulating film 31 is e.g. a silicon oxide film.

Alternatively, the tunnel insulating film 31 may be a stacked film of the structure in which a charge trapping layer is sandwiched between a pair of silicon oxide films. In the tunnel insulating film 31, the erase operation can be performed with a lower electric field than in a monolayer silicon oxide film.

For example, the stacked film described above can be made of ONO film. In addition, the charge trapping layer can be e.g. made of a silicon nitride.

The block insulating film 35 prevents the charge accumulated in the charge accumulation film 32 from diffusing into the electrode layer WL. The block insulating film 35 includes a cap film 34 provided in contact with the electrode layer WL, and a block film 33 provided between the cap film 34 and the charge accumulation film 32.

The block film 33 is e.g. a silicon oxide film. The cap film 34 is a film having a higher permittivity than silicon oxide. The cap film 34 is made of e.g. silicon nitride film or aluminum oxide. The cap film 34 thus provided in contact with the electrode layer WL can suppress back-tunneling electrons injected from the electrode layer WL at erase time. That is, charge blocking performance can be improved by forming the block insulating film 35 as a stacked film of e.g. silicon oxide film and silicon nitride film.

In the case of writing data to a memory cell MC, the electrode layer WL of the memory cell MC that should be written is applied with a write potential Vprog (e.g., approximately 20 V). The electrode layer WL of the memory cell MC not to be written is applied with a pass potential (or intermediate potential) Vpass (e.g., approximately 10 V) lower than Vprog. Thus, the intensity of electric field applied to the charge accumulation film 32 is increased only in the memory cell MC to be written.

As shown in FIG. 1, a drain side select transistor STD is provided in the upper end part of the columnar part CL in the memory string MS. A source side select transistor STS is provided in the lower end part.

The memory cell, the drain side select transistor STD, and the source side select transistor STS are vertical transistors in which the current flows in the stacking direction (Z-direction) of the stacked body 100.

The drain side select gate SGD functions as a gate electrode (control gate) of the drain side select transistor STD. An insulating film functioning as a gate insulating film of the drain side select transistor STD is provided between the drain side select gate SGD and the channel body 20.

The source side select gate SGS functions as a gate electrode (control gate) of the source side select transistor STS. An insulating film functioning as a gate insulating film of the source side select transistor STS is provided between the source side select gate SGS and the channel body 20.

A plurality of memory cells MC are provided between the drain side select transistor STD and the source side select transistor STS. In each memory cell MC, the electrode layer WL serves as a control gate.

The plurality of memory cells MC, the drain side select transistor STD, and the source side select transistor STS are series connected through the channel body 20 to constitute one memory string MS. This memory string MS is arranged in a plurality in the X-direction and the Y-direction. Thus, a plurality of memory cells is provided three-dimensionally in the X-direction, the Y-direction, and the Z-direction.

As shown in FIG. 2, the columnar part CL includes a semiconductor film 51. The semiconductor film 51 is provided inside the channel body 20 and surrounded with the channel body 20. The semiconductor film 51 is provided above the portion of the columnar part CL penetrating through the drain side select gate SGD. The semiconductor film 51 is in contact with the upper surface of the core insulating film 50.

The semiconductor film 51 is e.g. a silicon film primarily composed of silicon. The semiconductor film 51 is made of e.g. polysilicon containing impurity. The impurity concentration of the semiconductor film 51 is higher than the impurity concentration of the channel body 20.

In a typical memory of the charge injection type, electrons written in the floating gate are extracted by increasing the substrate potential. As an alternative method for erasure, GIDL (gate induced drain leakage) erasure can be used. In this method, the channel potential of the memory cell is boosted using the GIDL current generated in the channel at the upper end of the drain side select gate SGD. In this case, holes are generated by applying a high electric field to the semiconductor film 51 having high impurity concentration formed near the upper end part of the drain side select gate SGD. The holes are supplied to the channel body 20 to increase the channel potential. The potential of the electrode layer WL is set to e.g. ground potential (0 V). Thus, electrons in the charge accumulation film 32 are extracted, or holes are injected into the charge accumulation film 32, by the potential difference between the channel body 20 and the electrode layer WL. Thus, data erase operation is performed.

A conductive film 52 is provided on the upper surface of the channel body 20 and the upper surface of the semiconductor film 51. The conductive film 52 covers the upper surface of the channel body 20 and the upper surface of the semiconductor film 51. The conductive film 52 is electrically connected to each of the channel body 20 and the semiconductor film 51. The conductive film 52 contains e.g. metal. The conductive film 52 is made of e.g. metal silicide.

A contact part CN is provided on the conductive film 52. The conductive film 52 is electrically connected to the bit line BL through the contact part CN.

The bit line BL is electrically connected to each of the channel body 20 and the semiconductor film 51 through the conductive film 52.

According to this embodiment, the conductive film 52 is provided between the channel body 20 and the contact part CN. That is, the channel body 20, the semiconductor film 51, and the contact part CN are each in contact with the conductive film 52. Thus, the contact resistance of each of the channel body 20 and the semiconductor film 51 can be made lower than that in the case of being in contact with the contact part CN made of a metal material. This can improve the efficiency of voltage application to the channel body 20 at e.g. erase time.

Next, an example of the method for manufacturing a semiconductor memory device of the embodiment is described with reference to FIGS. 4A to 6B. However, the manufacturing method of this embodiment is not limited to the method described below.

As shown in FIG. 4A, a source side select gate SGS is formed via an insulating layer 41 on a substrate 10. A stacked body 15 is formed on the source side select gate SGS. Insulating layers 40 and electrode layers WL are alternately stacked in the stacked body 15.

A drain side select gate SGD is formed on the insulating layer 40a formed in the uppermost layer of the stacked body 15. An insulating layer 42 is formed on the drain side select gate SGD. The insulating layer 42 is made of e.g. silicon oxide film.

As shown in FIG. 4B, memory holes MH are formed. The memory hole MH penetrates in the stacking direction from the insulating layer 42 to the insulating layer 41 and reaches the substrate 10. The memory hole MH is formed by e.g. RIE (reactive ion etching) technique using a mask, not shown. The substrate 10 is exposed at the bottom surface of the memory hole MH.

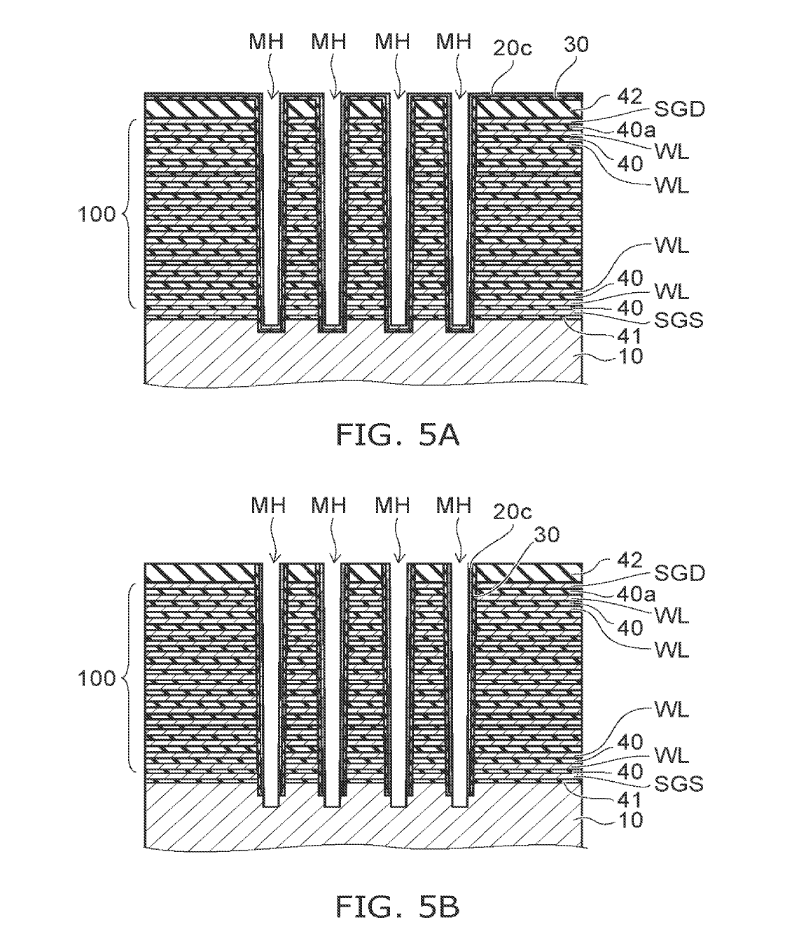

As shown in FIG. 5A, a memory film 30 shown in FIG. 3 is formed on the inner wall (side surface and bottom surface) of the memory hole MH and on the insulating layer 42. A cover film 20c is formed inside the memory film 30. The cover film 20c protects the side surface of the memory film 30 in the processing of the bottom surface of the memory hole MH described later. The cover film 20c is made of e.g. the same material as the channel body 20. The following description describes the case of forming a cover film 20c. However, the manufacturing of this embodiment is also possible using a process without forming this cover film 20c.

As shown in FIG. 5B, the cover film 20c and the memory film 30 formed on the bottom surface of the memory hole MH are removed. The cover film 20c and the memory film 30 are removed by e.g. RIE technique using a mask, not shown. Thus, the substrate 10 is exposed at the bottom surface of the memory hole MH. At this time, the cover film 20c and the memory film 30 formed on the upper surface of the insulating film 42 are also removed. Thus, the upper surface of the insulating layer 42 is exposed.

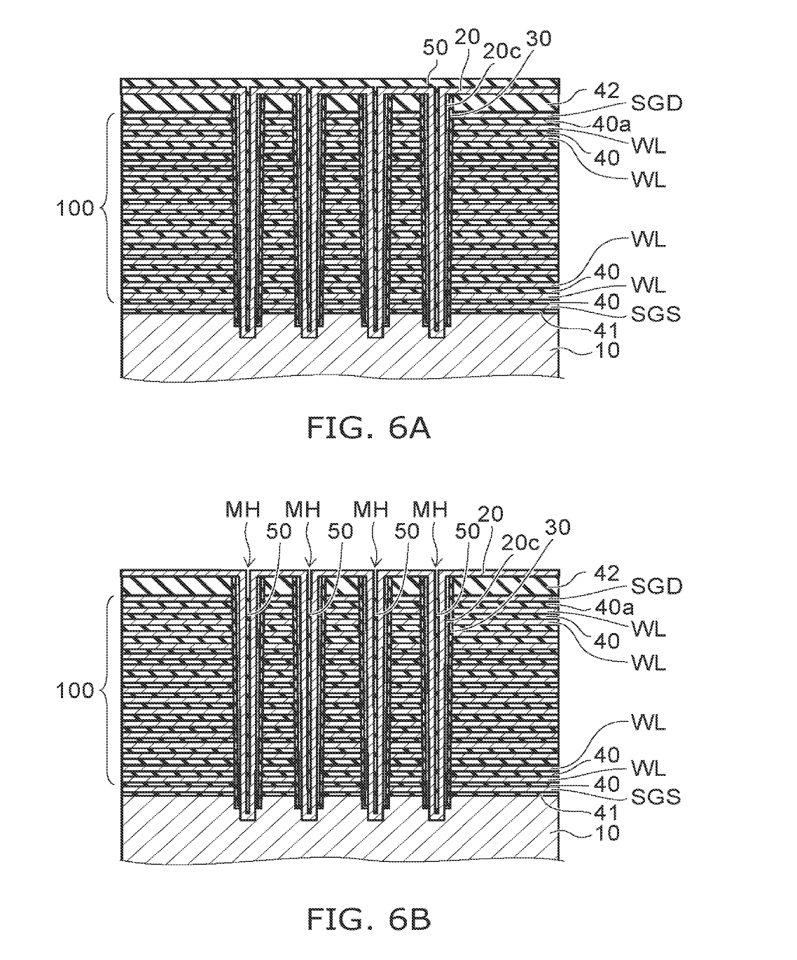

As shown in FIG. 6A, a channel body 20 is formed inside the cover film 20c. A core insulating film 50 is formed inside the channel body 20. The channel body 20 is formed also on the bottom surface of the memory hole MH. Thus, the channel body 20 is connected to the substrate 10 electrically.

As shown in FIG. 6B, the core insulating film 50 formed in the memory hole MH is set back by e.g. RIE technique. Thus, the upper surface of the core insulating film 50 is set back from the upper end of the memory hole MH to the portion on which the insulating layer 42 is stacked. The height of the upper surface of the core insulating film 50 is higher than the height of the upper surface of the drain side select gate SGD. At this time, the core insulating film 50 deposited on the stacked body 15 is also removed.

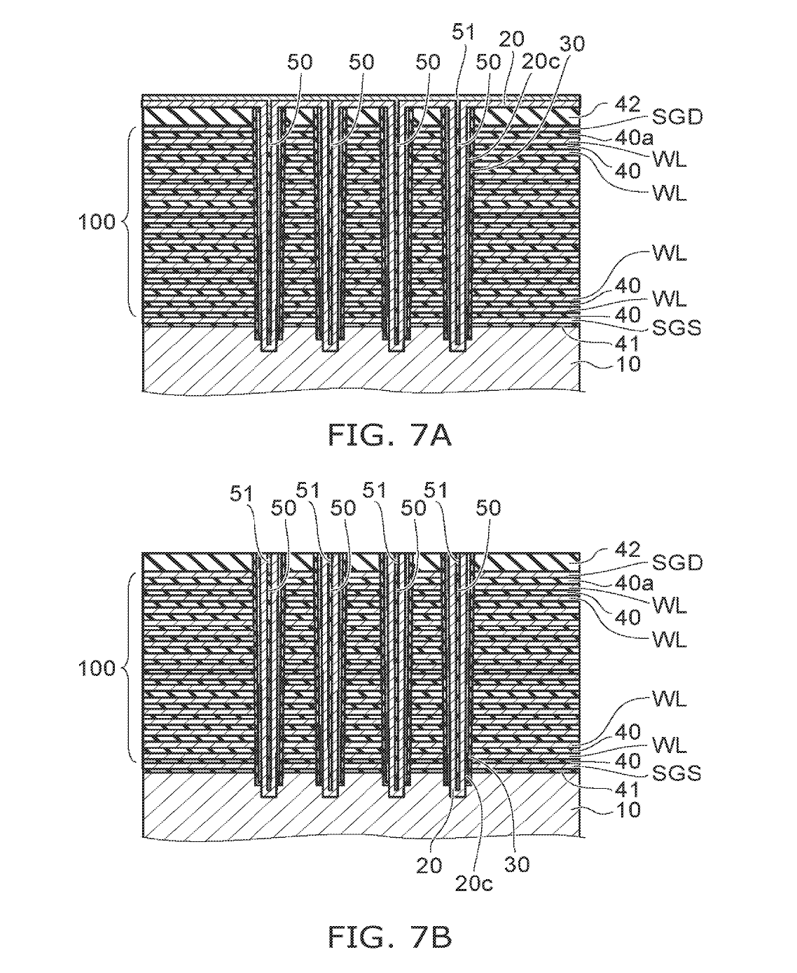

As shown in FIG. 7A, a semiconductor film 51 is formed in the portion of the memory hole MH where the core insulating film 50 is set back. The semiconductor film 51 is formed on the upper end part of the memory hole MH. The side surface of the semiconductor film 51 is covered with the channel body 20 and electrically connected to the channel body 20. Thus, a columnar part CL is formed.

The bottom surface of the semiconductor film 51 is in contact with the upper surface of the core insulating film 50. The height of the lower surface of the semiconductor film 51 is higher than the height of the upper surface of the drain side select gate SGD.

As shown in FIG. 7B, the semiconductor film 51 and the channel body 20 formed on the portion other than the columnar part CL are removed by e.g. RIE technique. Thus, the upper surface of the insulating layer 42 is exposed.

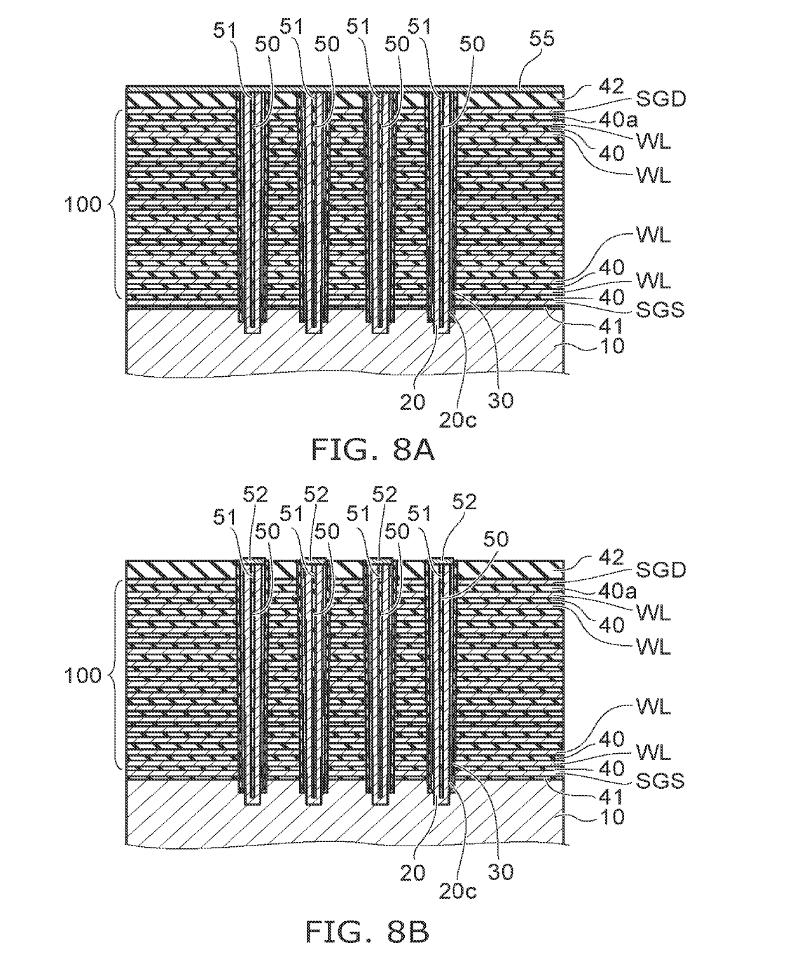

As shown in FIG. 8A, a metal film 55 is formed on the columnar part CL and on the insulating layer 42. The metal film 55 is made of e.g. a metal (such as nickel, cobalt, and titanium) used for metal silicidation. Subsequently, heating treatment is performed. Thus, silicon contained in the channel body 20 and the semiconductor film 51 at the upper end of the columnar part CL reacts with the metal film 55. Accordingly, a conductive film 52 made of metal silicide film is formed at the upper end of the columnar part CL.

As shown in FIG. 8B, the excess unreacted metal film 55 is removed by e.g. wet etching technique. Thus, the conductive film 52 is formed only on Si in the upper end part. The conductive film 52 is formed so as to cover the upper surface of the columnar part CL.

Alternatively, the conductive film 52 may be formed from e.g. a film containing metal. In this case, pattern processing is performed by photolithography technique. Thus, the conductive film 52 formed on other than the columnar part CL is removed.

Thus, the conductive film 52 is electrically connected to each of the channel body 20 and the semiconductor film 51. The conductive film 52 is used as an etching stopper film in forming the hole 43h described later.

Subsequently, an insulating layer 43 is formed on the insulating layer 42 and on the columnar part CL. The insulating layer 43 is made of e.g. silicon oxide film.

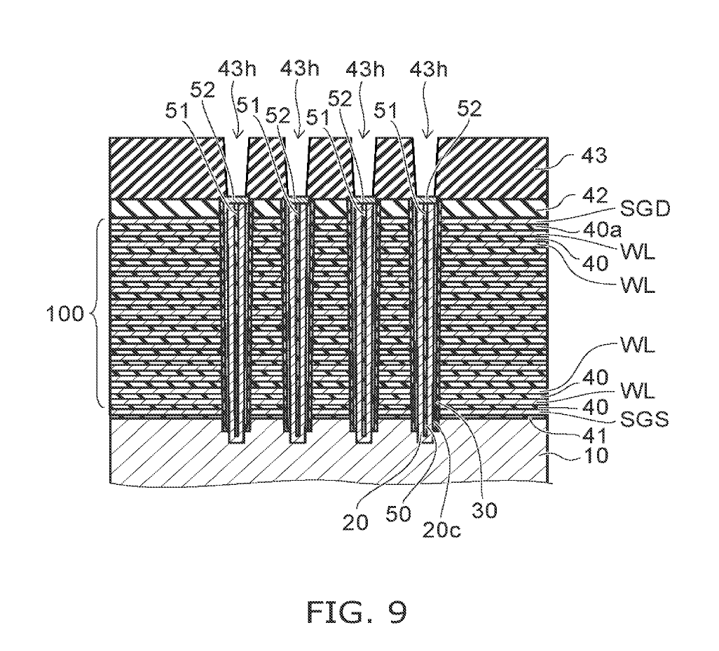

As shown in FIG. 9, hole 43h penetrating through the insulating layer 43 is formed. The hole 43h penetrates through the insulating layer 43 and reaches the columnar part CL. At this time, the conductive film 52 is used as an etching stopper so that the hole 43h does not reach into the columnar part CL.

Next, a conductive material (e.g., tungsten) is embedded in the hole 43h. Thus, a contact part CN shown in FIG. 2 is formed. The contact part CN is electrically connected to the channel body 20 and the semiconductor film 51 through the conductive film 52.

Subsequently, bit lines BL and the like shown in FIG. 1 are formed on the contact part CN. Thus, the semiconductor memory device of this embodiment is formed.

According to this embodiment, a conductive film 52 is formed at the upper end of the columnar part CL. The conductive film 52 is a film made of a material having high selection ratio (resistance) to etching of the insulating layer 43. Thus, the conductive film 52 can be used as an etching stopper film for forming the hole 43h. This improves the accuracy in the depth direction of the hole 43h. The semiconductor film 51 is not eliminated in this etching. Thus, the embedding depth of the semiconductor film 51 can be optimized in a shallower range.

Furthermore, the variation in the depth direction of the hole 43h is decreased. This can reduce the margin distance of the drain side select gate SGD for the variation of the hole 43h and the accuracy of characteristics control of the drain side select gate SGD can be improved. It can make the memory to be downsized.

This embodiment can improve the flexibility of the design of the select gate, and the flexibility of the shape of the carrier source (e.g., semiconductor film 51) of the channel. Thus, the controllability of the device operation can be improved. Furthermore, electrical connection between the contact part CN and the columnar part CL can be ensured with high accuracy.

FIG. 10 is an enlarged schematic sectional view of part of a columnar part of an alternative embodiment.

This embodiment is different from the aforementioned embodiment in the structure of the upper part (semiconductor film 51 and conductive film 52) of the columnar part CL. Thus, description of the portions similar to those of the aforementioned embodiment is omitted.

As shown in FIG. 10, the columnar part CL includes a semiconductor film 51. The semiconductor film 51 is provided on the channel body 20 and on the core insulating film 50. The semiconductor film 51 covers each of the upper surface of the channel body 20 and the upper surface of the core insulating film 50. The semiconductor film 51 covers e.g. all the upper surface of the columnar part CL.

The semiconductor film 51 is e.g. a silicon film primarily composed of silicon. The semiconductor film 51 is made of e.g. polysilicon containing impurity. The impurity concentration of the semiconductor film 51 is higher than the impurity concentration of the channel body 20. The side surface of the semiconductor film 51 may be covered with e.g. the memory film 30. The upper surface of the memory film 30 may be covered with the semiconductor film 51.

A conductive film 52 is provided on the semiconductor film 51. That is, the semiconductor film 51 is provided between the channel body 20 and the conductive film 52. The conductive film 52 covers the upper surface of the semiconductor film 51. The conductive film 52 contains e.g. metal. The conductive film 52 is made of e.g. metal silicide.

A contact part CN is provided on the conductive film 52. The conductive film 52 is electrically connected to the bit line BL through the contact part CN.

The bit line BL is electrically connected to the channel body 20 through the conductive film 52 and the semiconductor film 51.

According to this embodiment, the conductive film 52 is provided between the channel body 20 and the contact part CN. The semiconductor film 51 is provided between the channel body 20 and the conductive film 52. That is, the channel body 20 is in contact with the semiconductor film 51. Thus, as in the aforementioned embodiment, the contact resistance of the channel body 20 can be made lower than that in the case of being in contact with the contact part CN made of a metal material. This can improve the efficiency of voltage application to the channel body 20 at e.g. erase time.

Furthermore, according to this embodiment, the semiconductor film 51 is provided on the channel body 20 and on the core insulating film 50. Thus, the total volume of the semiconductor film 51 can be made larger than that in the case where the semiconductor film 51 is provided inside the channel body 20. This can improve the efficiency of charge injection into the channel body 20.

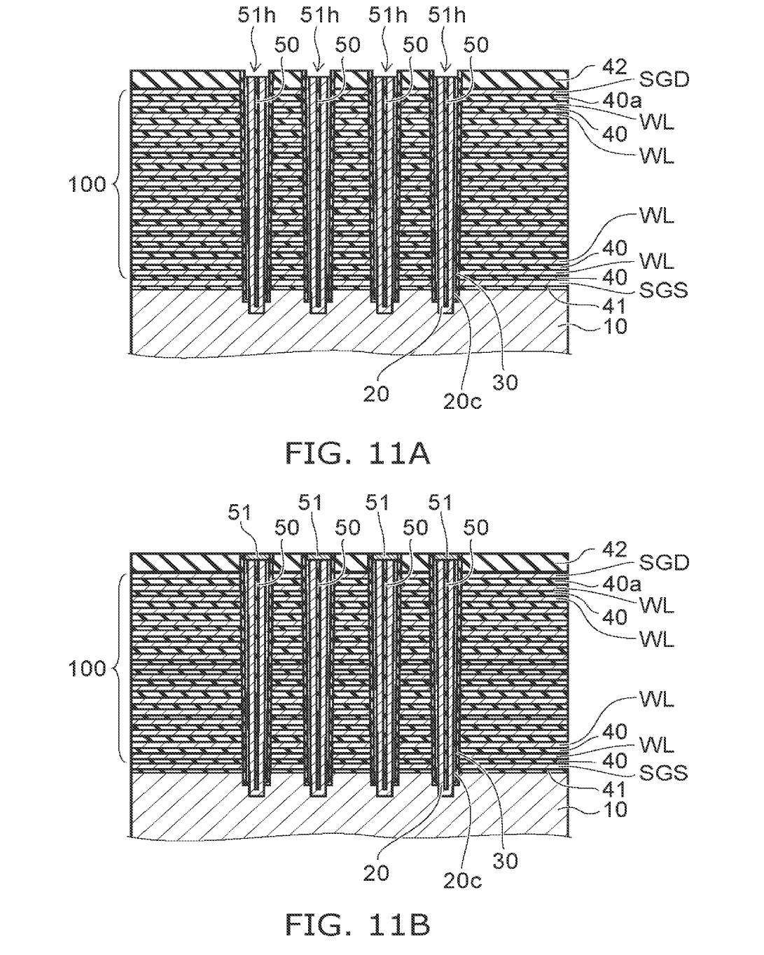

Next, an example of the method for manufacturing a semiconductor memory device of the alternative embodiment is described with reference to FIGS. 11A to 15. As an example, the following description describes the case of forming a cover film 20c. However, a manufacturing method without forming the cover film 20c is also possible. The point of the embodiments of the invention does not depend on the formation of the cover film 20c.

As in the description of FIGS. 4A to 6A described above, a source side select gate SGS is formed via an insulating layer 41 on a substrate 10. A stacked body 15 is formed on the source side select gate SGS. Insulating layers 40 and electrode layers WL are alternately stacked in the stacked body 15.

A drain side select gate SGD is formed on the insulating layer 40a formed in the uppermost layer of the stacked body 15. An insulating layer 42 is formed on the drain side select gate SGD. The insulating layer 42 is made of e.g. silicon oxide film.

Next, memory holes MH are formed. The memory hole MH penetrates in the stacking direction from the insulating layer 42 to the insulating layer 41 and reaches the substrate 10. The memory hole MH is formed by e.g. RIE technique using a mask, not shown. The substrate 10 is exposed at the bottom surface of the memory hole MH.

Subsequently, a memory film 30 shown in FIG. 3 is formed on the inner wall of the memory hole MH and on the insulating layer 42. A cover film 20c is formed inside the memory film 30. The cover film 20c is made of e.g. the same material as the channel body 20.

Next, the cover film 20c and the memory film 30 formed on the bottom surface of the memory hole MH are removed. The cover film 20c and the memory film 30 are removed by e.g. RIE technique using a mask, not shown. Thus, the substrate 10 is exposed at the bottom surface of the memory hole MH.

Subsequently, a channel body 20 is formed inside the cover film 20c. A core insulating film 50 is formed inside the channel body 20. The channel body 20 is formed also on the bottom surface of the memory hole MH. Thus, the channel body 20 is in contact with the substrate 10.

As shown in FIG. 11A, the core insulating film 50, the channel body 20, and the memory film 30 formed on the stacked body 15 are sequentially removed. Thus, an opening 51h of the memory hole MH is formed. At this time, the upper end of the core insulating film 50, the channel body 20, and the memory film 30 formed in the memory hole MH is also removed by recess technique based on e.g. wet etching. The opening 51h may be formed like e.g. a taper in which the center side of the memory hole MH is set back relative to the side surface side. That is, the memory film 30 may be formed on the side surface of the opening 51h of the memory hole MH.

The height of the bottom surface of the opening 51h of the memory hole MH is higher than the height of the upper surface of the drain side select gate SGD.

As shown in FIG. 11B, a semiconductor film 51 is formed in the opening 51h of the memory hole MH. At this time, the semiconductor film 51 formed also on the stacked body 15 is removed by e.g. wet etching technique. Thus, a columnar part CL is formed.

The upper surface of the channel body 20 and the upper surface of the core insulating film 50 are covered with the semiconductor film 51. The side surface of the semiconductor film 51 may be covered with e.g. the memory film 30. The upper surface of the memory film 30 may be covered with the semiconductor film 51.

Next, as in the description of FIG. 8A, a metal film 55 is formed on the columnar part CL and the insulating layer 42. The metal film 55 is made of e.g. a metal (such as nickel, cobalt, and titanium) used for metal silicidation. Subsequently, heating treatment is performed. Thus, silicon contained in the semiconductor film 51 at the upper end of the columnar part CL reacts with the metal film 55. Accordingly, a conductive film 52 made of metal silicide film is formed at the upper end of the columnar part CL.

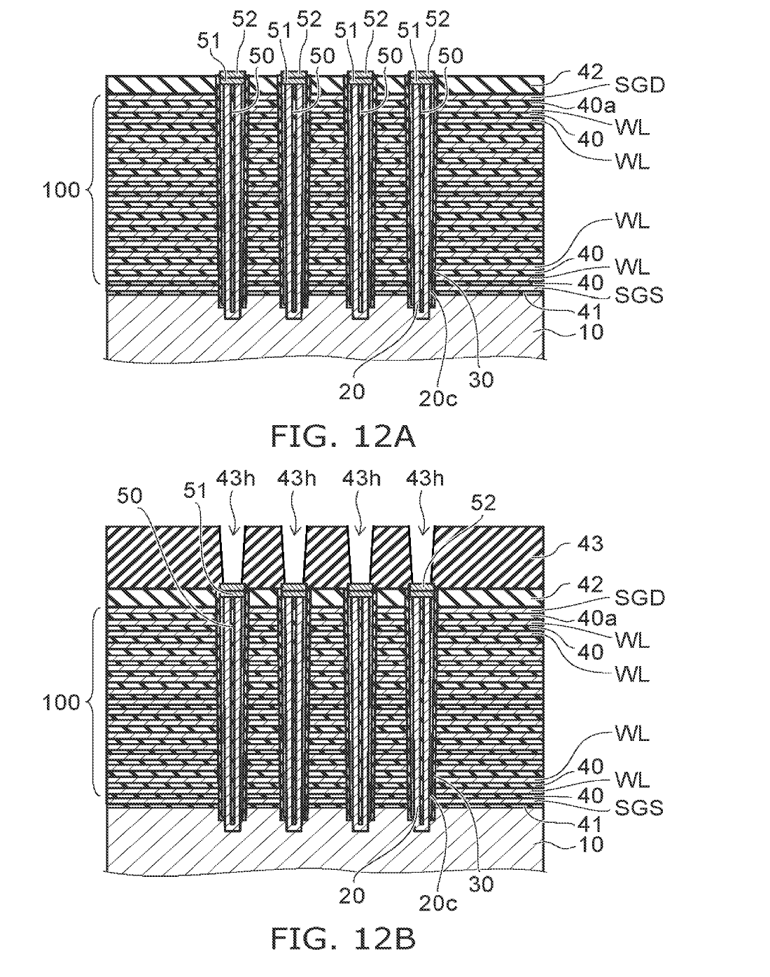

As shown in FIG. 12A, the excess unreacted metal film 55 is removed by e.g. wet etching technique. Thus, the conductive film 52 is formed only at the upper end of the columnar part CL. The conductive film 52 is formed so as to cover the upper surface of the columnar part CL.

Alternatively, the conductive film 52 may be formed from e.g. a film containing metal. In this case, pattern processing is performed by photolithography technique. Thus, the conductive film 52 formed on other than the columnar part CL is removed.

Thus, the conductive film 52 is electrically connected to the semiconductor film 51. The conductive film 52 is used as an etching stopper film in forming the hole 43h described later.

Subsequently, an insulating layer 43 is formed on the insulating layer 42 and on the columnar part CL. The insulating layer 43 is made of e.g. silicon oxide film.

As shown in FIG. 12B, holes 43h penetrating through the insulating layer 43 are formed. The hole 43h penetrates through the insulating layer 43 and reaches the columnar part CL. At this time, the conductive film 52 is used as an etching stopper and controlled so that the hole 43h does not reach into the columnar part CL.

Next, a conductive material is embedded in the hole 43h. Thus, a contact part CN shown in FIG. 10 is formed. The contact part CN is electrically connected to the channel body 20 through the conductive film 52 and the semiconductor film 51.

Subsequently, bit lines BL and the like shown in FIG. 1 are formed on the contact part CN. Thus, the semiconductor memory device of this embodiment is formed.

According to this embodiment, as in the aforementioned embodiment, a conductive film 52 is formed at the upper end of the columnar part CL. Thus, the conductive film 52 can be used as an etching stopper film for forming the hole 43h. This improves the accuracy in the depth direction of the hole 43h. The semiconductor film 51 is not eliminated in this etching. Thus, the embedding depth of the semiconductor film 51 can be optimized in a shallower range.

Furthermore, the variation in the depth direction of the hole 43h is decreased. This can reduce the margin distance of the drain side select gate SGD for the variation of the hole 43h. Thus, the accuracy of characteristics control of the drain side select gate SGD can be improved, and the memory can be downsized.

In addition to the foregoing, the contact resistance between the contact part CN and the conductive film 52 is lower than the contact resistance between the contact part CN and each of the channel body 20 and the semiconductor film 51. Thus, the resistance from the contact part CN to the channel body 20 can be reduced. This can improve the efficiency of voltage application to the channel body 20 at e.g. erase time.

According to this embodiment, in contrast to the aforementioned embodiment, the semiconductor film 51 is formed between the conductive film 52 and the channel body 20. This facilitates metal silicidation in forming the conductive film 52. Furthermore, forming the semiconductor film 51 in the opening 51h of the memory hole MH is easier than forming the semiconductor film 51 inside the channel body 20. Moreover, the carrier source (semiconductor film 51) of the drain part of the memory string MS can be sufficiently ensured. This can improve the carrier injection efficiency.

Furthermore, according to this embodiment, the conductive film 52 (metal silicide) is formed entirely on the upper surface of the columnar part CL. This can suppress the influence caused by misalignment in the width direction of the hole 43h on the memory film 30 and the channel body 20 in the columnar part CL.

This embodiment can improve the flexibility of the design of the select gate, and the flexibility of the shape of the carrier source (semiconductor film 51) of the channel. Thus, the controllability of the device operation can be improved. Furthermore, electrical connection between the contact part CN and the columnar part CL can be ensured with high accuracy.

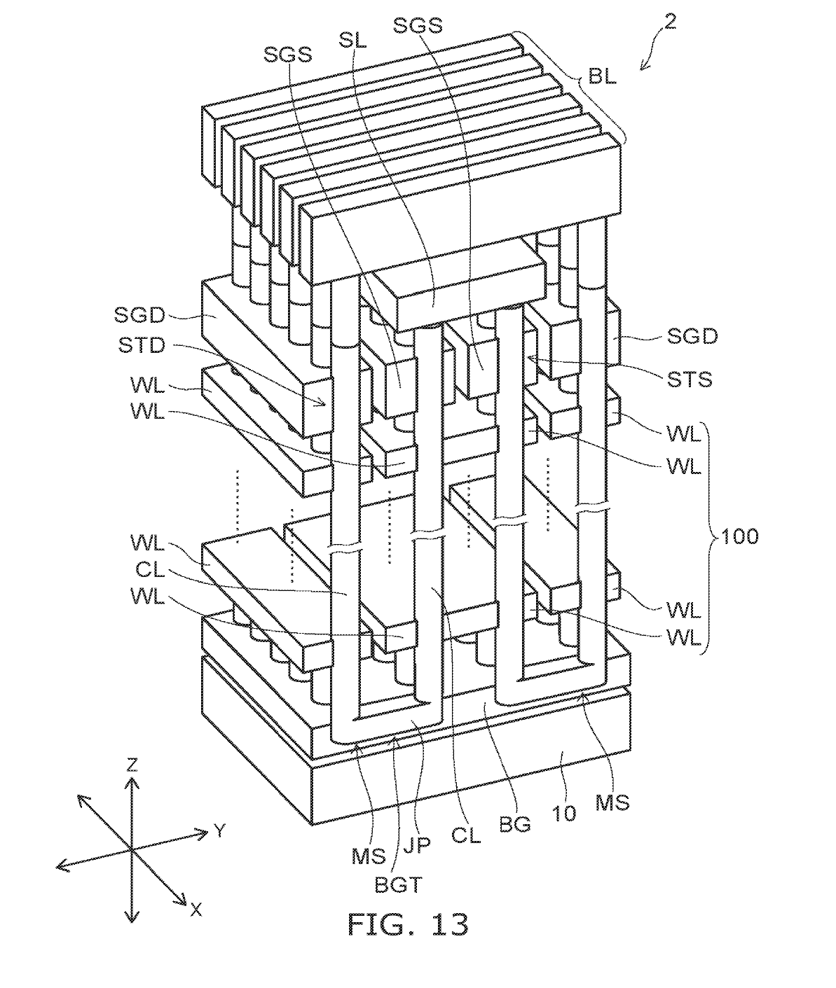

FIG. 13 is a schematic perspective view of a memory cell array 2 of an alternative example of the semiconductor memory device of the embodiment. Also in FIG. 13, as in FIG. 1, insulating layers, for instance, are not shown for clarity of illustration.

A back gate BG is provided via an insulating layer on a substrate 10. A stacked body 100 is provided on the back gate BG. A plurality of electrode layers WL and a plurality of insulating layers 40 are stacked alternately in the stacked body 100.

One memory string MS is formed in a U-shape. The memory string MS includes a pair of columnar parts CL extending in the Z-direction, and a junction part JP joining the respective lower ends of the pair of columnar parts CL. The columnar part CL is formed like e.g. a circular or elliptic cylinder. The columnar part CL penetrates through the stacked body and reaches the back gate BG.

A drain side select gate SGD is provided in one upper end part of a pair of columnar parts CL in the U-shaped memory string MS. A source side select gate SGS is provided in the other upper end part. The drain side select gate SGD and the source side select gate SGS are provided via an insulating layer 40a on the uppermost electrode layer WL.

The drain side select gate SGD and the source side select gate SGS are separated in the Y-direction by a separation part 60. The stacked body below the drain side select gate SGD and the stacked body below the source side select gate SGS are separated in the Y-direction by the separation part 60. That is, the stacked body between a pair of columnar parts CL of the memory string MS is separated in the Y-direction by the separation part 60.

A source layer SL is provided via an insulating layer on the source side select gate SGS. A plurality of bit lines (e.g., metal films) BL are provided via an insulating layer on the drain side select gate SGD and the source layer SL. Each bit line BL extends in the Y-direction.

Also in the memory cell array 2 shown in FIG. 13, as in the aforementioned embodiment, the conductive film 52 is provided between the channel body 20 and the contact part CN. Thus, as in the aforementioned embodiment, the contact resistance between the channel body 20 and the contact part CN can be reduced. This can improve the efficiency of voltage application to the channel body 20 at e.g. erase time.

Furthermore, the conductive film 52 can be used as an etching stopper for forming the contact part to the columnar part CL. This improves the accuracy in the depth direction.

This embodiment can improve the flexibility of the design of the select gate, and the flexibility of the shape of the carrier source (semiconductor film 51) of the channel. Thus, the controllability of the device operation can be improved. Furthermore, electrical connection between the contact part CN and the columnar part CL can be ensured with high accuracy.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a stacked body including a plurality of electrode layers separately stacked each other;
a semiconductor body provided in the stacked body and extending in stacking direction of the stacked body;
a charge accumulation film provided between the semiconductor body and the plurality of electrode layers;
a conductive film provided on the semiconductor body and containing a metal;
a contact part provided on the conductive film and electrically connected to the conductive film; and
a semiconductor film provided below the conductive film, being in contact with the semiconductor body and the conductive film, and having a higher impurity concentration than the semiconductor body.

2. The device according to claim 1, further comprising a select gate provided on the stacked body and surrounding the semiconductor body.

3. The device according to claim 2, wherein the semiconductor film is provided above a upper surface of the select gate.

4. The device according to claim 1, wherein the semiconductor film is provided inside the semiconductor body.

5. The device according to claim 4, wherein the conductive film is provided on an upper surface of the semiconductor body and an upper surface of the semiconductor film.

6. The device according to claim 1, wherein
the semiconductor film is provided between the semiconductor body and the conductive film, and
an upper surface of the semiconductor body is entirely covered with the semiconductor film.

7. The device according to claim 6, wherein an upper surface of the semiconductor body is covered with the semiconductor film.

8. The device according to claim 1, wherein an upper surface of the semiconductor film is covered with the conductive film.

9. The device according to claim 1, wherein
the semiconductor body and the semiconductor film contain silicon, and
the conductive film contains metal silicide.

10. The device according to claim 1, further comprising an insulating film provided inside the semiconductor body and being in contact with the semiconductor film.

11. A semiconductor memory device comprising:
a stacked body including a plurality of electrode layers separately stacked each other;
a semiconductor body provided in the stacked body and extending in stacking direction of the stacked body;
a charge accumulation film provided between the semiconductor body and the plurality of electrode layers;
a conductive film provided on the semiconductor body and containing metal silicide; and
a contact part provided on the conductive film and electrically connected to the conductive film.

12. The device according to claim 11, further comprising a select gate provided on the stacked body and surrounding the semiconductor body.

13. The device according to claim 12, wherein the conductive film is provided above a upper surface of the select gate.

14. A method for manufacturing a semiconductor memory device, comprising:
forming a stacked body including a plurality of electrode layers and a plurality of insulating layers, the plurality of electrode layers separately stacked each other, the plurality of insulating layers provided between the plurality of electrode layers;
forming a hole penetrating through the stacked body and extending in stacking direction of the stacked body;
forming a film including a charge accumulation film on an inner wall of the hole;
forming a semiconductor body inside the film including the charge accumulation film;
forming a semiconductor film having a higher impurity concentration than the semiconductor body on an upper end part of the hole;
forming a conductive film containing a metal on the semiconductor body and the semiconductor film; and
forming a contact part on the conductive film, the contact part being in contact with the conductive film.

15. The method according to claim 14, wherein the semiconductor film is formed inside an upper end part of the semiconductor body.

16. The method according to claim 14, wherein the semiconductor film is formed on an upper surface of the semiconductor body.

17. The method according to claim 14, wherein the forming the contact part includes:
forming an insulating film on the conductive film;
forming a hole penetrating through the insulating film and reaching the conductive film; and
forming a conductive material in the hole.

18. The method according to claim 14, wherein the semiconductor body and the semiconductor film contain silicon.

19. The method according to claim 18, wherein the forming the conductive film includes:
forming a metal film on the upper surface of the semiconductor body and the upper surface of the semiconductor film; and
forming a metal silicide film on the upper surface of the semiconductor body and the upper surface of the semiconductor film by reacting the silicon of the semiconductor body and the semiconductor film with metal of the metal film.

20. The method according to claim 19, wherein the metal film contains at least one of nickel, cobalt, and titanium.
